(19) United States
(12) Patent Application Publication
(10) Pub. No.: US 2026/0052669 A1
(43) Pub. Date: Feb. 19, 2026

(54) SEMICONDUCTOR DEVICE

(71) Applicant: Samsung Electronics Co., Ltd., Suwon-si (KR)

(72) Inventors: Younjin JANG, Suwon-si (KR); Kyooho JUNG, Suwon-si (KR); Sangwook KIM, Suwon-si (KR); Jeeeun YANG, Suwon-si (KR)

(73) Assignee: Samsung Electronics Co., Ltd., Suwon-si (KR)

(21) Appl. No.: 19/184,225

(22) Filed: Apr. 21, 2025

(30) Foreign Application Priority Data
Aug. 19, 2024 (KR) 10-2024-0110766

(51) Int. Cl. H10B 12/00

(52) U.S. Cl. CPC H10B 12/30

(57) ABSTRACT

Provided is a semiconductor device. The semiconductor device includes an oxide semiconductor layer including a first metal, a metal layer spaced apart from the oxide semiconductor layer, a metal nitride layer between the metal layer and the oxide semiconductor layer and including a second metal that is different from the first metal, a metal oxide layer between the metal nitride layer and the oxide semiconductor layer and including the first metal and the second metal.

### CROSS-REFERENCE TO RELATED APPLICATION

This application is based on and claims priority under 35 U.S.C. § 119 to Korean Patent Application No. 10-2024-0110766, filed on Aug. 19, 2024, in the Korean Intellectual Property Office, the disclosure of which is incorporated by reference herein in its entirety.

### BACKGROUND

### 1. Field

One or more example embodiments relate to semiconductor devices.

### 2. Description of the Related Art

A transistor is a semiconductor device with an electrical switching function and is used in various integrated circuit devices including memory devices, driving integrated circuits (ICs), logic devices, etc. In order to improve the integration degree of an IC device, a space occupied by a transistor arranged therein is being rapidly reduced, and accordingly, research for maintaining performance of a transistor while reducing a size of the transistor is being actively performed.

An oxide semiconductor transistor uses an oxide semiconductor material as a channel layer. As compared with an example in which silicon is used as a channel layer, a channel layer may have higher mobility even in an amorphous state and may be formed evenly in a relatively large area. Also, an oxide semiconductor transistor has a lower leakage current based on a wider bandgap of about 3.0 eV or greater and a small hole carrier concentration characteristic.

However, when the oxide semiconductor transistor is applied directly as a semiconductor device, a contact resistance may largely affect an operating performance of the transistor because the size of the transistor is reduced. For example, a total resistance of the transistor may be determined as a sum of a resistance of a channel layer and a contact resistance between an electrode (e.g., source or drain electrode) and the channel layer. The total resistance of the transistor may be largely affected by the magnitude of the contact resistance as the length of the channel layer is reduced. The contact resistance may increase when metal reacts with a relatively strong oxidant such as ozone during manufacturing processes or may further increase due to subsequent relatively high-temperature processes.

### SUMMARY

One or more example embodiments provide semiconductor devices having reduced deterioration in contact resistance while maintaining thermal reliability at a higher temperature.

One or more example embodiments provide semiconductor devices having a dual-layered intermediate layer between an oxide semiconductor layer and a metal layer.

One or more example embodiments provide semiconductor devices including a layer reducing or preventing a material in an oxide semiconductor layer from flowing into a metal layer, and a layer reducing or preventing an increase in contact resistance.

Additional aspects will be set forth in part in the description which follows and, in part, will be apparent from the description, or may be learned by practice of the presented example embodiments of the disclosure.

According to an example embodiment, a semiconductor device includes an oxide semiconductor layer including a first metal, a first electrode and a second electrode spaced apart from each other on the oxide semiconductor layer, a metal nitride layer between at least one of the first electrode and the second electrode and the oxide semiconductor layer, the metal nitride layer including a second metal that is different from the first metal, a metal oxide layer between the metal nitride layer and the oxide semiconductor layer, the metal oxide layer including the first metal and the second metal, a gate electrode spaced apart from the oxide semiconductor layer, and a gate insulating layer between the oxide semiconductor layer and the gate electrode, wherein a content of the first metal in the metal oxide layer is less than a content of the first metal in the oxide semiconductor layer.

The content of the first metal in the metal oxide layer may be less than a content of the second metal in the metal oxide layer.

The content of the first metal in the metal oxide layer may be less than or equal to 10 at %.

The metal nitride layer may have 0 at % of oxygen.

The metal oxide layer may further include nitrogen.

A content of nitrogen may decrease from the metal nitride layer toward the oxide semiconductor layer.

At least one of the metal nitride layer or the metal oxide layer may further include silicon (Si).

The second metal may be different from a third metal included in an electrode in contact with the metal nitride layer from among the first electrode and the second electrode.

The first metal may include at least one of indium (In), gallium (Ga), tin (Sn), cadmium (Cd), aluminum (Al), germanium (Ge), or hafnium (Hf).

The second metal may include at least one of Ga, tungsten (W), zinc (Zn), vanadium (V), titanium (Ti), molybdenum (Mo), niobium (Nb), or tantalum (Ta).

The metal nitride layer may include TiN, and the metal oxide layer may include InTiO, and a content of indium in the metal oxide layer may be 10 at % or less.

A thickness of the metal oxide layer may be less than a thickness of the metal nitride layer.

A thickness of the metal oxide layer may be half a thickness of the metal nitride layer or less.

A contact resistance between an electrode in contact with the metal nitride layer from among the first electrode and the second electrode and the oxide semiconductor layer may be 3E−2 Ω·cm² or less.

The first electrode, the metal nitride layer, the metal oxide layer, the oxide semiconductor layer, and the second electrode may be sequentially arranged in a direction perpendicular to a surface of the first electrode.

A width of the metal oxide layer may be equal to a width of the metal nitride layer.

The oxide semiconductor layer may include a first region extending in a direction parallel to the surface of the first electrode and a second region extending from the first electrode to the second electrode, in a direction perpendicular to the first electrode.

The metal oxide layer may include a third region between the metal nitride layer and the first region of the oxide semiconductor layer, and a fourth region surrounding an outer surface of the second region.

The metal nitride layer may include a first metal nitride layer between the first electrode and the oxide semiconductor layer, and a second metal nitride layer between the second electrode and the oxide semiconductor layer, and the metal oxide layer may include a first metal oxide layer between the first metal nitride layer and the oxide semiconductor layer, and a second metal oxide layer between the second metal nitride layer and the oxide semiconductor layer.

The semiconductor device may further include a capacitor electrically connected to the oxide semiconductor layer, wherein the first electrode may be a component of a bit line and a gate electrode may be a component of a word line.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a diagram showing a semiconductor device according to an example embodiment;

FIG. 2 is a graph showing an IV characteristic of a transistor according to a comparative example;

FIG. 3 is a graph showing an IV characteristic of a transistor according to an example embodiment;

FIG. 4 is a diagram showing a semiconductor device according to an example embodiment;

FIG. 5 is a diagram showing a semiconductor device according to another example embodiment;

FIG. 6 is a diagram showing a semiconductor device according to another example embodiment;

FIG. 7 is a diagram showing a semiconductor device according to another example embodiment;

FIG. 8 is a diagram showing a semiconductor device according to another example embodiment;

FIG. 9 is a diagram showing a semiconductor device according to another example embodiment;

FIG. 10 is a diagram showing a semiconductor device according to another example embodiment;

FIG. 11 is a diagram showing a semiconductor device according to another example embodiment;

FIG. 12 is a perspective view showing an example of a schematic structure of a vertical stack memory device according to an example embodiment;

FIG. 13 is a perspective view showing an example of a schematic structure of a vertical stack memory device according to another example embodiment;

FIG. 14 is a block diagram of an electronic system according to an example embodiment; and

FIG. 15 is a block diagram of an electronic system according to an example embodiment.

### DETAILED DESCRIPTION

Reference will now be made in detail to some example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the disclosed example embodiments are merely described below, by referring to the figures, to explain aspects. As used herein, the term “and/or” includes any and all combinations of one or more of the associated listed items. Expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, a semiconductor device and a method of manufacturing the same according to some example embodiments are described in detail with reference to accompanying drawings. In the drawings, like reference numerals denote like components, and sizes of components in the drawings may be exaggerated for convenience of explanation.

An expression used in the singular encompasses the expression of the plural, unless it has a clearly different meaning in the context. It will be further understood that when a portion is referred to as “comprising” another component, the portion may not exclude another component but may further comprise another component unless the context states otherwise. Also, in the drawings, a size or thickness of each component may be exaggerated for clarity of description. In the following description, when a layer is described to exist on another layer, the layer may exist directly on a substrate or the other layer or another layer may be interposed therebetween. In addition, because materials forming each layer in the following example embodiments are examples, other materials may be used.

Also, the terms “ . . . unit”, “ . . . module” used herein specify a unit for processing at least one function or operation, and this may be implemented with hardware or software or a combination of hardware and software.

The particular implementations shown and described herein are illustrative examples of some example embodiments and are not intended to otherwise limit the technical scope of example embodiments in any way. For the sake of brevity, electronics, control systems, software, and other functional aspects of the systems according to the related art may not be described in detail.

Furthermore, the connecting lines or connectors shown in the drawings are intended to represent example functional relationships and/or physical or logical couplings between the various elements. It should be noted that many alternative or additional functional relationships, physical connections, or logical connections may be present in a practical device.

The use of the term of “the above-described” and similar indicative terms may correspond to both the singular forms and the plural forms.

Also, the steps of all methods described herein may be performed in any suitable order unless otherwise indicated herein or otherwise clearly contradicted by context. Also, the use of some example terms (for example, etc.) is only to describe a technical spirit in detail, and the scope of rights is not limited by these terms unless the context is limited by the claims.

Expressions such as “at least one of,” when preceding a list of elements, modify the entire list of elements and do not modify the individual elements of the list. For example, the expression, “at least one of a, b, and c,” should be understood as including only a, only b, only c, or a combination of two or more of A, B, and C such as ABC, AB, BC and AC.

When the terms “about” or “substantially” are used in this specification in connection with a numerical value, it is intended that the associated numerical value include a tolerance of +10% around the stated numerical value. Moreover, when the words “generally” and “substantially” are used in connection with geometric shapes, it is intended that precision of the geometric shape is not required but that latitude for the shape is within the scope of the disclosure. Additionally, regardless of whether a value or shape is limited by “about” or “substantially,” such value and shape may be construed to include manufacturing or operating tolerance (e.g., +10%) around the stated numerical value.

It will be understood that although the terms “first” and “second” are used herein to describe various elements, these elements should not be limited by these terms. Terms are only used to distinguish one element from other elements.

The use of any and all examples, or example language provided herein, is intended merely to better illuminate the disclosure and does not pose a limitation on the scope of the present disclosure unless otherwise claimed.

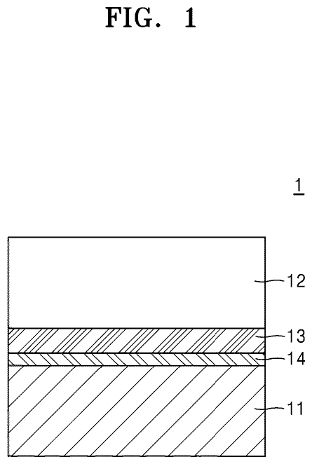

FIG. 1 is a diagram showing a semiconductor device 1 according to an example embodiment. The semiconductor device 1 of FIG. 1 may be a transistor or an element of a memory cell. The transistor may be a different element from the memory cell or may be an element of a memory cell. Referring to FIG. 1, the semiconductor device 1 may include an oxide semiconductor layer 11, a metal layer 12 spaced apart from the oxide semiconductor layer 11, a metal nitride layer 13 disposed between the oxide semiconductor layer 11 and the metal layer 12, and a metal oxide layer 14 disposed between the oxide semiconductor layer 11 and the metal nitride layer 13.

The oxide semiconductor layer 11 according to an example embodiment may include a plurality of metals. The oxide semiconductor layer 11 may include an oxide of a material selected from Group 12, 13, and 14 metal such as indium (In), gallium (Ga), tin (Sn), cadmium (Cd), aluminum (Al), germanium (Ge), hafnium (Hf), and zinc (Zn), and a combination thereof. For example, the oxide semiconductor may include InSnO, InGaSnO, InGaZnO, InSnZnO, GaSnZnO, ZnSnO, etc. The oxide semiconductor layer 11 may be provided as a single-layered or multi-layered structure. The oxide semiconductor layer 11 may have a thickness of about 20 nm or less, about 10 nm or less, about 8 nm or less, or about 7 nm or less. The oxide semiconductor layer 11 may have a length of about 1 μm or less, about 500 nm or less, about 100 nm or less, about 50 nm or less, or about 30 nm or less. When the semiconductor device 1 is a transistor or an element of a memory cell, the oxide semiconductor layer 11 may be a channel layer. Here, a length of the oxide semiconductor layer 11 or a channel layer may denote a distance between two electrodes (e.g., source and drain) electrically connected to the oxide semiconductor layer, and a thickness of the oxide semiconductor layer 11 may be a dimension of a direction perpendicular to the length.

Indium (In) has a low bond dissociation energy with oxygen and relatively easily forms oxygen vacancies, so as to improve a charge carrier concentration in the oxide semiconductor layer 11, and may sufficiently form an electron-conducting pathway through s orbitals of the fifth period. Therefore, the oxide semiconductor layer 11 according to an example embodiment may include indium. However, because indium (In) is thermally unstable, when the indium (In) is dominantly included in the oxide semiconductor layer 11, the electrical characteristics of the oxide semiconductor layer 11 may vary according to the temperature. For example, when the heat of about 400° C. or greater is applied to the oxide semiconductor layer 11, indium (In) is dispersed or distributed in the oxide semiconductor layer 11, and thus, the oxide semiconductor layer 11 may lose its semiconductor characteristics, but may have a conductive characteristic.

The oxide semiconductor layer 11 according to an example embodiment include a plurality of metals including indium (In), but a content amount of indium (In) with respect to the plurality of metals may be less than about 50 at %, about 40 at % or less, about 35 at % or less, about 10 at % or less, or greater than about 5 at %. Hereinafter, a content of certain metal in a certain layer denotes a content of the certain metal from among the metals included in the certain layer, and a content of a certain non-metal in a certain layer may denote a content of a certain non-metal from among non-metals included in the certain layer.

The semiconductor device 1 according to an example embodiment may include the metal layer 12 spaced apart from the oxide semiconductor layer 11. The metal layer 12 may only include metal. The metal layer 12 may include at least one of tungsten (W), cobalt (Co), nickel (Ni), steel (Fe), titanium (Ti), molybdenum (Mo), chrome (Cr), zirconium (Zr), hafnium (Hf), niobium (Nb), tantalum (Ta), argentum (Ag), aurum (Au), aluminum (Al), copper (Cu), tin (Sn), vanadium (V), ruthenium (Ru), platinum (Pt), zinc (Zn), or magnesium (Mg).

The metal layer 12 may have a thickness of about 20 nm or less. For example, the metal layer 12 may have a thickness of about 1 nm or greater, about 3 nm or greater, or about 5 nm or greater, about 15 nm or less, about 10 nm or less, or about 7 nm or less.

When the semiconductor device 1 is an element of the memory cell, the metal layer 12 may be a partial region in a bit line. Alternatively, when the semiconductor device 1 is an element of the transistor, the metal layer 12 may be a source electrode or a drain electrode.

When the semiconductor device 1 according to an example embodiment operates as a transistor, a threshold voltage of the semiconductor device 1 may be about −0.5 V to about +0.5 V. In addition, a contact resistance of the semiconductor device 1 may be about 3E−2 (that is, 3×10⁻²) Ω·cm² or less.

The semiconductor device 1 according to an example embodiment may further include an additional layer between the oxide semiconductor layer 11 and the metal layer 12. The semiconductor device 1 according to an example embodiment may further include a metal nitride layer 13 between the oxide semiconductor layer 11 and the metal layer 12. The metal nitride layer 13 may be in direct contact with the metal layer 12. The metal nitride layer 13 may reduce or prevent inter-diffusion between the oxide semiconductor layer 11 and the metal layer 12 due to a relatively strong bonding force of nitrogen.

The metal nitride layer 13 may be a conductive material including metal. The metal included in the metal nitride layer 13 may be different from at least one of the metal included in the oxide semiconductor layer 11 and the metal included in the metal layer 12. For example, the metal nitride layer 13 may be a nitride including at least one of Ga, W, Zn, V, Ti, Mo, or Nb. The metal nitride layer may not include oxygen. That is, a content of oxygen in the metal nitride layer 13 may be 0 at %. For example, when the metal layer 12 include W, the metal nitride layer 13 may include TiN.

A thickness of the metal nitride layer 13 may be less than that of the metal layer 12. For example, the thickness of the metal nitride layer 13 may be ½ or less of the thickness of the metal layer 12. The thickness of the metal nitride layer 13 may be about 10 nm or less. The thickness of the metal nitride layer 13 may be about 0.1 nm or greater, about 0.3 nm or greater, about 0.5 nm or greater, about 0.8 nm or greater, or about 1 nm or greater, and about 8 nm or less, about 7 nm or less, about 6 nm or less, or about 5 nm or less.

The metal nitride layer 13 may reduce or prevent the material diffusion between the oxide semiconductor layer 11 and the metal layer 12, and at the same time, may increase the contact resistance. The semiconductor device 1 according to an example embodiment may further include a metal oxide layer 14 disposed between the oxide semiconductor layer 11 and the metal nitride layer 13 and including a plurality of metals. The metal oxide layer 14 may have a resistance lower than that of the metal nitride layer. The metal oxide layer 14 may be in direct contact with at least one of the metal nitride layer 13 or the oxide semiconductor layer 11.

The metal oxide layer 14 may include a first metal included in the oxide semiconductor layer 11 and a second metal included in the metal nitride layer 13. The first metal may be at least one of In, Ga, Sn, Cd, Al, Ge, or Hf, and the second metal may be at least one of Ga, W, Zn, V, Ti, Mo, or Nb. For example, when the metal nitride layer 13 includes TiN and the oxide semiconductor layer 11 includes InGaZnO, the metal oxide layer 14 may include InTiO.

When the metal oxide layer 14 only includes the second metal included in the metal nitride layer 13, the contact resistance may increase. However, the metal oxide layer 14 according to an example embodiment includes the first metal included in the oxide semiconductor layer 11 and the second metal included in the metal nitride layer 13, and thus the metal oxide layer 14 may have a relatively low-resistive property and may improve interfacial characteristics between layers.

In the metal oxide layer 14, the content of the first metal may be less than the content of the first metal in the oxide semiconductor layer 11. Here, the content of the first metal may denote an average content in the metal oxide layer 14 or in the oxide semiconductor layer 11. In the oxide semiconductor layer 11, the first metal forms the oxygen vacancies, but in the metal oxide layer 14, the first metal improves the resistive characteristics. Thus, the content of the first metal in the oxide semiconductor layer 11 may be relatively very small.

The content of the first metal in the metal oxide layer 14 may be less than the content of the second metal in the metal oxide layer 14. For example, from among the metals included in the metal oxide layer 14, the content of the first metal may be about 10 at % or less. The content of the first metal may vary depending on the region in the metal oxide layer 14. For example, in the interface between the metal oxide layer 14 and the metal nitride layer 13, the content of the first metal may be less than that of the first metal in the interface between the metal oxide layer 14 and the oxide semiconductor layer 11. In some example embodiments, the content of the first metal may increase from the metal oxide layer 13 toward the oxide semiconductor layer 11.

At least one of the metal nitride layer 13 or the metal oxide layer 14 may further include silicon (Si). By including Si having semiconductor characteristics, the metal nitride layer 13 or the metal oxide layer 14 may have improved semiconductor characteristics.

The thickness of the metal oxide layer 14 may be less than that of the metal nitride layer 13. For example, the thickness of the metal oxide layer 14 may be about half the thickness of the metal nitride layer 13 or less. The metal oxide layer 14 may have the thickness of about 3 nm or less. The thickness of the metal oxide layer 14 may be about 0.1 nm or greater, about 0.5 nm or greater, or about 1 nm or greater, and may be about 3 nm or less. Alternatively, the metal oxide layer 14 may have the thickness of about 0.5 nm to about 5 nm.

In the semiconductor device 1 according to an example embodiment, the metal oxide layer 14 may be formed in a part of the metal nitride layer 13. The metal oxide layer 14 may be formed by adding the first metal and oxygen to a partial region of the metal nitride layer 13. The metal oxide layer 14 may include nitrogen. The nitrogen content of the metal oxide layer 14 at the interface between the metal oxide layer 14 and the metal nitride layer 13 may be greater than that of the metal oxide layer 14 at the interface between the metal oxide layer 14 and the oxide semiconductor layer 11. For example, the nitrogen content in the metal oxide layer 14 may be reduced from the metal nitride layer 13 toward the oxide semiconductor layer 11. In some example embodiments, an oxygen content in the metal oxide layer 14 at the interface between the metal oxide layer 14 and the metal nitride layer 13 may be less than that in the metal oxide layer 14 at the interface between the metal oxide layer 14 and the oxide semiconductor layer 11. For example, the oxygen content in the metal oxide layer 14 may increase from the metal nitride layer 13 toward the oxide semiconductor layer 11.

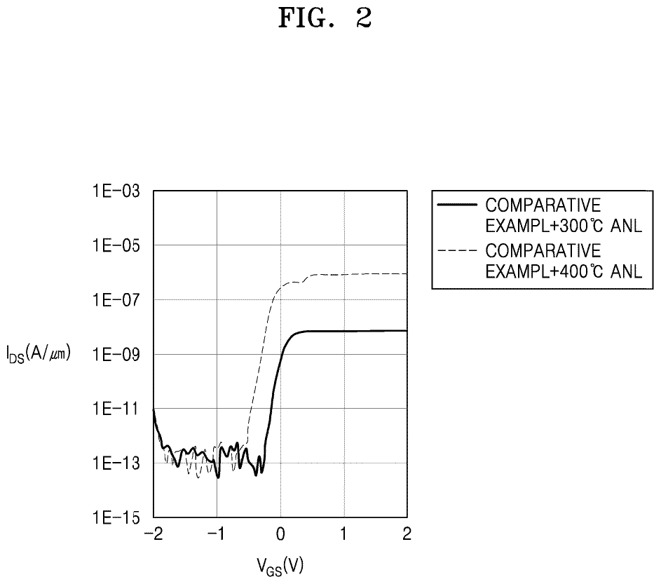

FIG. 2 shows a comparative example, and is a graph showing IV characteristics with respect to a transistor including a channel layer formed of InGaZnO (In:Ga:Zn=3:2:1), an electrode formed of W, and a single layer including TiN between the channel layer and the electrode. In addition, a voltage (VDs) between the source and drain is about 1 V.

In FIG. 2, a solid line is IV characteristics with respect to the transistor thermally treated at 300° C. according to the comparative example, and a dashed-line denotes IV characteristics with respect to the transistor thermally treated at about 400° C. according to the comparative example.

Referring to FIG. 2, the transistor thermally treated at 300° C. of the comparative example has a threshold voltage of about 0.1 V, and the transistor thermally treated at 400° C. has a threshold voltage of about −0.3 V. Here, the threshold voltage may denote a voltage when a current of 1E−10 A/μm or greater flows in the channel layer.

In addition, the transistor thermally treated at 300° C. of the comparative example has an on-current of 4.7E−9 A/μm and the transistor thermally treated at 400° C. of the comparative example has an on-current of 1E−6 A/μm. Here, the on-current may denote a current value at a voltage adding 1 V to the threshold voltage. When the contact resistance between the channel layer and the electrode is calculated based on the threshold voltage and the on-current, the contact resistance of the transistor thermally treated at 300° C. of the comparative example is about 4.2E+2 Ω·cm² and the contact resistance of the transistor thermally treated at 400° C. of the comparative example is about 4.3E−3 Ω·cm². Because the contact resistance of the transistor thermally treated at 300° C. is 4.2E+2 Ω·cm², it may be identified that the transistor according to the comparative example has a relatively high contact resistance.

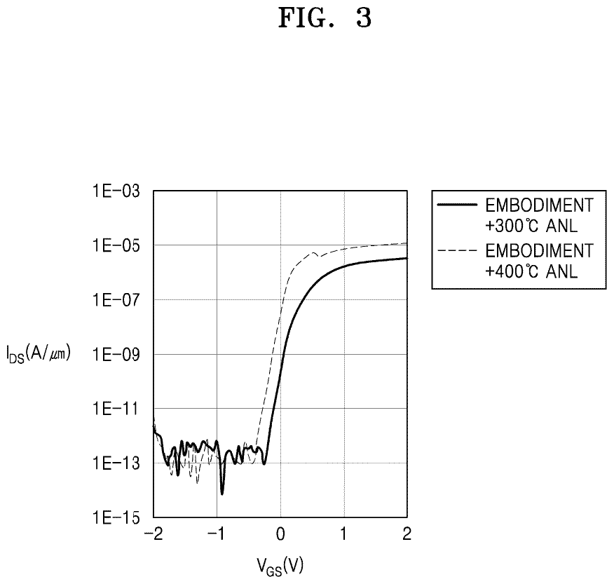

FIG. 3 is a graph showing IV characteristics with respect to a transistor according to an example embodiment, the transistor having a channel layer formed of or including InGaZnO (In:Ga:Zn=3:2:1), an electrode formed of W, and a multiple layers between the channel layer and the electrode. The transistor according to the example embodiment include a metal nitride layer including TiN and a metal oxide layer including InTiO (In 10 at %) between the channel layer and the electrode. In FIG. 3, a solid line is IV characteristics with respect to the transistor thermally treated at about 300° C., and a dashed-line denotes IV characteristics with respect to the transistor thermally treated at about 400° C.

Referring to FIG. 3, the transistor thermally treated at about 300° C. has a threshold voltage of about 0.1 V, and the transistor thermally treated at about 400° C. has a threshold voltage of about −0.1 V. Here, the threshold voltage may denote a voltage when a current of 1E−10 A/μm or greater flows in the channel layer. The transistor including a single layer (e.g., a TiN layer) has the threshold voltage shifted by about 0.4 V due to the thermal treatment, but the transistor including a plurality of layers (e.g., a TiN layer and an InTiO layer (In 10 at %)) has the threshold voltage shifted by about 0.2 V due to the thermal treatment. Reduction in a shifted amount of the threshold voltage denotes improved thermal stability.

In addition, the transistor thermally treated at 300° C. according to the example embodiment has an on-current of 7.6E−7 A/μm, and the transistor thermally treated at about 400° C. according to the embodiment has an on-current of 5.4E−6 A/μm. When the contact resistance between the channel layer and the electrode is calculated based on the threshold voltage and the on-current, the contact resistance of the transistor thermally treated at 300° C. is about 2.6E−2 Ω·cm² and the contact resistance of the transistor thermally treated at about 400° C. is about 2.2E−4 Ω·cm². The contact resistance of the transistor in which a plurality of layers (e.g., the TiN layer and the InTiO layer (In 10 at %)) are disposed between the channel layer and the electrode is less than the contact resistance of the transistor in which a single layer (e.g., TiN layer) is disposed between the channel layer and the electrode. Thus, it may be predicted that the transistor including a plurality of intermediate layers according to some example embodiments may have a reduced contact resistance under the thermal treatment or at a relatively high temperature and may more stably operate.

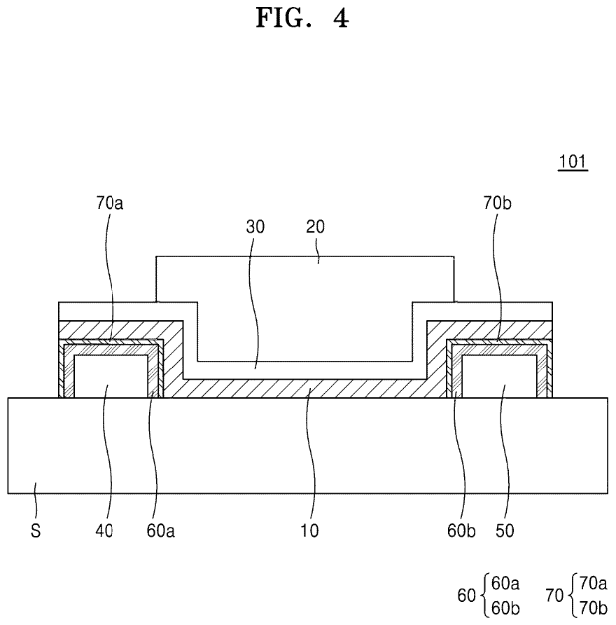

FIG. 4 is a diagram showing a semiconductor device 101 according to an embodiment. The semiconductor device 101 of FIG. 4 may include an oxide semiconductor layer 10, a gate electrode 20 spaced apart from the oxide semiconductor layer 10, a gate insulating layer 30 disposed between the oxide semiconductor layer 10 and the gate electrode 20, and a first electrode 40 and a second electrode 50 that are disposed on the oxide semiconductor layer 10 and are spaced apart from each other.

The oxide semiconductor layer 10 may be the same as or substantially similar to the oxide semiconductor layer 11 described above with reference to FIG. 1, and detailed descriptions thereof are omitted.

The gate electrode 20 may be spaced apart from the oxide semiconductor layer 10. The gate insulating layer 30 may be disposed between the oxide semiconductor layer 10 and the gate electrode 20. The gate electrode 20 may include at least one of metal, metal nitride, or transparent conductive oxide (TCO). The gate insulating layer 30 may include oxide including at least one of Hf, Zr, Al, or Si. When the semiconductor device 101 is an element of a memory cell, the gate electrode 20 may be a partial region in a word line.

The first electrode 40 and the second electrode 50 may be disposed on the oxide semiconductor layer 10 to be spaced apart from each other. For example, the first electrode 40 and the second electrode 50 are disposed on a lower surface of the oxide semiconductor layer 10, and the gate electrode 20 may be disposed on an upper surface of the oxide semiconductor layer 10. However, example embodiments are not limited thereto. The first electrode 40, the second electrode 50, and the gate electrode 20 may be disposed on the same surface of the oxide semiconductor layer 10. The first electrode 40 may be a source electrode, and the second electrode 50 may be a drain electrode. At least one of the first electrode 40 or the second electrode 50 may correspond to the metal layer 12 described above with reference to FIG. 1, and detailed descriptions thereof are omitted.

The metal nitride layer 60 may be further disposed between at least one of the first electrode 40 or the second electrode 50 and the oxide semiconductor layer 10. The metal nitride layer 60 may include a first metal nitride layer 60a disposed between the first electrode 40 and the oxide semiconductor layer 10, and a second metal nitride layer 60b disposed between the second electrode 50 and the oxide semiconductor layer 10. The first metal nitride layer 60a and the second metal nitride layer 60b may be spaced apart from each other. At least one of the first metal nitride layer 60a or the second metal nitride layer 60b may correspond to the metal nitride layer 13 described above with reference to FIG. 1, and detailed descriptions thereof are omitted.

The metal oxide layer 70 may be further disposed between the oxide semiconductor layer 10 and the metal nitride layer 60. The metal oxide layer 70 may include a first metal oxide layer 70a disposed between the oxide semiconductor layer 10 and the first metal nitride layer 60a, and a second metal oxide layer 70b disposed between the oxide semiconductor layer 10 and the second metal nitride layer 60b. At least one of the first metal oxide layer 70a or the second metal oxide layer 70b corresponds to the metal oxide layer 14 described above with reference to FIG. 1, and detailed descriptions thereof are omitted.

FIG. 4 shows that the metal nitride layer 60 and the metal oxide layer 70 are disposed between the first electrode 40 and the oxide semiconductor layer 10 and between the second electrode 50 and the oxide semiconductor layer 10, but example embodiments are not limited thereto. In the semiconductor device 101, the metal nitride layer 60 and the metal oxide layer 70 may be disposed only between the first electrode 40 and the oxide semiconductor layer 10 or between the second electrode 50 and the oxide semiconductor layer 10. The second metal included in the metal nitride layer 60 may be different from a third metal included in an electrode in contact with the metal nitride layer from among the first electrode 40 and the second electrode 50.

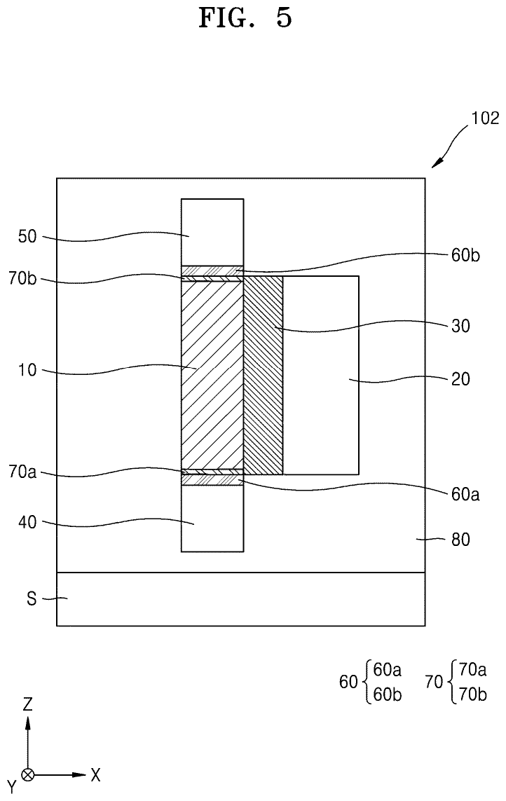

FIG. 5 is a diagram showing a semiconductor device 102 according to another example embodiment. In FIG. 5, components indicated by the same reference numerals as those of FIG. 4 have substantially the same structures and effects as those described with reference to FIG. 4, and thus, detailed descriptions thereof are omitted.

Referring to FIG. 5, the semiconductor device 102 may include a substrate S, the first electrode 40 disposed on the substrate S, the oxide semiconductor layer 10 disposed on the first electrode 40, and the second electrode 50 disposed on the oxide semiconductor layer 10.

The oxide semiconductor layer 10 may be arranged so that the lengthwise direction thereof is in a direction (Z-axis direction) perpendicular to the substrate S. In the specification, the lengthwise direction may denote a direction from the first electrode toward the second electrode.

The first electrode 40 and the second electrode 50 may be arranged to be spaced apart from each other in the direction (Z-axis direction) perpendicular to the substrate S. For example, the first electrode 40, the oxide semiconductor layer 10, and the second electrode 50 may be arranged in a row in a direction perpendicular to the substrate S or a thickness direction (Z-axis direction) of the first electrode 40.

The semiconductor device 102 may further include the first metal nitride layer 60a disposed between the first electrode 40 and the oxide semiconductor layer 10, the first metal oxide layer 70a disposed between the first metal nitride layer 60a and the oxide semiconductor layer 10, the second metal nitride layer 60b disposed between the second electrode 50 and the oxide semiconductor layer 10, and the second metal oxide layer 70b disposed between the second metal nitride layer 60b and the oxide semiconductor layer 10. The materials included in the oxide semiconductor layer 10, the gate electrode 20, the gate insulating layer 30, the first electrode 40, the second electrode 50, the first metal nitride layer 60a, the second metal nitride layer 60b, the first metal oxide layer 70a, and the second metal oxide layer 70b are described above, and thus, detailed descriptions thereof are omitted.

In the drawings, the first metal nitride layer 60a, the first metal oxide layer 70a, the second metal nitride layer 60b, and the second metal oxide layer 70b are shown, but example embodiments are not limited thereto. The semiconductor device 102 may only include the first metal nitride layer 60a and the first metal oxide layer 70a, or may only include the second metal nitride layer 60b and the second metal oxide layer 70b.

The gate electrode 20 may be arranged on one side of the oxide semiconductor layer 10. The gate insulating layer 30 may be disposed between the oxide semiconductor layer 10 and the gate electrode 20. The gate electrode 20 may be arranged so that the lengthwise direction (Z-axis direction) of the gate electrode 20 may be perpendicular to the substrate S. The oxide semiconductor layer 10, the gate insulating layer 30, and the gate electrode 20 may be arranged in a row in the direction (X-axis direction) parallel to the substrate S.

An insulating layer 80 may be arranged in the substrate S to fill the empty spaces. The first electrode 40 may be arranged to be spaced apart from the substrate S due to the insulating layer 80.

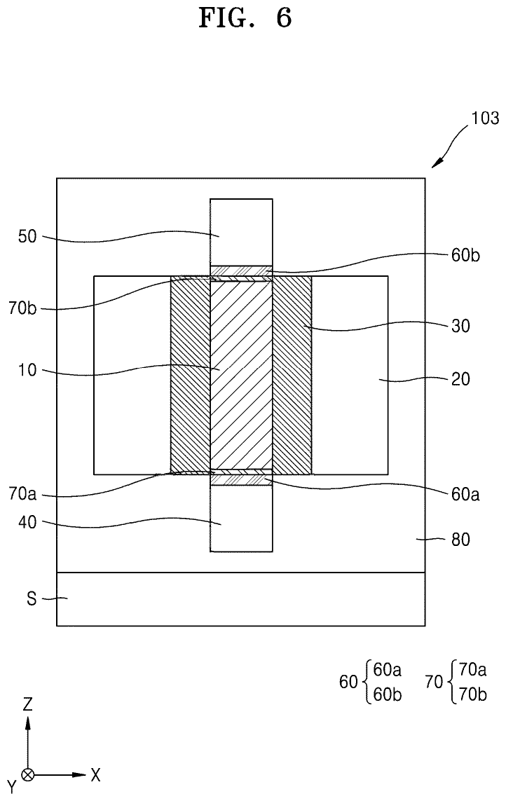

FIG. 6 is a diagram showing a semiconductor device 103 according to another example embodiment. In FIG. 6, components indicated by the same reference numerals as those of FIG. 4 have substantially the same structures and effects as those described with reference to FIG. 4, and thus, detailed descriptions thereof are omitted.

The semiconductor device 103 shown in FIG. 6 may include the first electrode 40, the oxide semiconductor layer 10, and the second electrode 50 that are arranged in the direction (Z-axis direction) perpendicular to the substrate S. The gate insulating layer 30 may be arranged on the boundary of the oxide semiconductor layer 10, and the gate electrode 20 may be arranged on the boundary of the gate insulating layer 30. Because the gate electrode 20 is arranged on the boundary of the oxide semiconductor layer 10, a facing area between the gate electrode 20 and the oxide semiconductor layer 10 may be increased, and a short-channel effect may be improved (e.g., reduced).

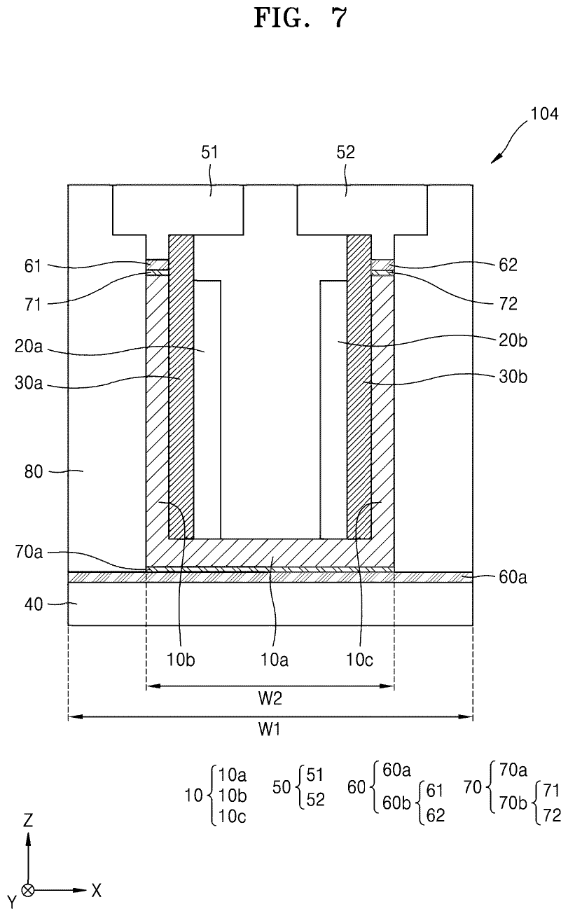

FIG. 7 is a diagram showing a semiconductor device 104 according to another example embodiment. In FIG. 7, components indicated by the same reference numerals as those described above have substantially the same structures and effects as those described above, and thus, detailed descriptions thereof are omitted.

The semiconductor device 104 shown in FIG. 7 may include the first electrode 40 and the oxide semiconductor layer 10 disposed on the first electrode 40.

The oxide semiconductor layer 10 may include a first region extending in a direction parallel to the surface of the first electrode 40 and a second region extending from the first electrode 40 toward the second electrode 50, in the aspect of the cross-sectional view taken along a direction perpendicular to the surface of the first electrode 40. For example, the oxide semiconductor layer 10 may have a U-shaped cross-section. The oxide semiconductor layer 10 may include a bottom portion 10a that is parallel to the surface of the first electrode, a first vertical extension portion 10b extending from one end of the bottom portion 10a in the direction (Z-axis direction) perpendicular to the surface of the first electrode, and a second vertical extension portion 10c extending from the other end of the bottom portion 10a in the direction (Z-axis direction) perpendicular to the surface of the substrate. A lower surface of the bottom portion 10a may be referred to as a lower surface of the oxide semiconductor layer 10, and outer surfaces of the first vertical extension portion and the second vertical extension portion may be referred to as outer surfaces of the oxide semiconductor layer 10. A width of the bottom portion in the oxide semiconductor layer 10 may be defined as a width of the oxide semiconductor layer 10.

The second electrode 50 may be disposed on the oxide semiconductor layer 10. The second electrode 50 may act as a landing pad. The second electrode 50 may include a first sub-electrode 51 and a second sub-electrode 52. The first sub-electrode 51 may be electrically connected to the first vertical extension portion 10b. The second sub-electrode 52 may be electrically connected to the second vertical extension portion 10c. The first sub-electrode 51 and the second sub-electrode 52 may not be electrically connected to each other.

In an example embodiment, an upper portion of each of the first sub-electrode 51 and the second sub-electrode 52 may have a first width in a first horizontal direction (X-axis direction), and a lower portion of each of the first sub-electrode 51 and the second sub-electrode 52 may have a second width that is less than the first width in the first horizontal direction (X-axis direction). Each of the first and second sub-electrodes 51 and 52 may have a vertical section formed in a T-shape.

A bottom surface of the lower portion of the first sub-electrode 51 is disposed on the upper surface of the first vertical extension portion 10b, and a bottom surface of the lower portion of the second sub-electrode 52 may be disposed on the upper surface of the second vertical extension portion 10c. The bottom surface of the lower portion of the second electrode 50 may be located at a higher level than that of an upper surface of a first gate electrode 20a and/or a second electrode 20b, and a side wall of the lower portion of the second electrode 50 may be partially covered by a first gate insulating layer 30a and/or a second gate insulating layer 30b.

The first metal nitride layer 60a may be disposed between the first electrode 40 and the oxide semiconductor layer 10, and the second metal nitride layer 60b may be disposed between the second electrode and the oxide semiconductor layer 10. In addition, the first metal oxide layer 70a may be disposed between the first metal nitride layer 60a and the oxide semiconductor layer 10, and the second metal oxide layer 70b may be disposed between the second metal nitride layer 60b and the oxide semiconductor layer 10.

A width W1 of the first metal nitride layer 60a in the direction (e.g., X-axis direction) parallel to the surface of the first electrode 40 may be greater than or equal to a width W2 of the oxide semiconductor layer 10 in the direction parallel to the surface of the first electrode 40. For example, a partial region of the first metal nitride layer 60a may overlap the oxide semiconductor layer 10 in the direction (e.g., Z-axis direction) perpendicular to the surface of the first electrode 40, and the remaining region of the first metal nitride layer 60a may not overlap the oxide semiconductor layer 10.

A width of the first metal oxide layer 70a may be less than or equal to the width of the first metal nitride layer 60a or greater than or equal to the width of the oxide semiconductor layer 10. For example, the width of the first metal oxide layer 70a may be equal to the width W2 of the oxide semiconductor layer 10.

The second metal nitride layer 60b may include a first sub-metal nitride layer 61 disposed between the first sub-electrode 51 and the first vertical extension portion 10b, and a second sub-metal nitride layer 62 disposed between the second sub-electrode 52 and the second vertical extension portion 10c. The width of each of the first sub-metal nitride layer 61 and the second sub-metal nitride layer 62 may be less than the width of the upper portion in each of the first sub-electrode 51 and the second sub-electrode 52.

The second metal oxide layer 70b may include a first sub-metal oxide layer 71 disposed between the first sub-metal nitride layer 61 and the first vertical extension portion 10b, and a second sub-metal oxide layer 72 disposed between the second sub-metal nitride layer 62 and the second vertical extension portion 10c. A width of the first sub-metal oxide layer 71 may be equal to the width of the first vertical extension portion 10b, and a width of the second sub-metal oxide layer 72 may be equal to the width of the second vertical extension portion 10c.

The gate electrode 20 may include a first gate electrode 20a spaced apart from the first vertical extension portion 10b, and a second gate electrode 20b spaced apart from the second vertical extension portion 10c. In addition, the gate insulating layer 30 may include a first gate insulating layer 30a disposed between the first vertical extension portion 10b and the first gate electrode 20a, and a second gate insulating layer 30b disposed between the second vertical extension portion 10c and the second gate electrode 20b.

The first gate electrode 20a and/or the second gate electrode 20b may extend in a second horizontal direction (Y-axis direction). The first gate electrode 20a and the second gate electrode 20b may be spaced apart from each other.

The semiconductor device 104 may have a vertical channel transistor (VCT) structure including a vertical channel region extending in the vertical direction (Z-axis direction) on the surface of the first electrode 40.

When the same electrical signal is applied to the first gate electrode 20a and the second gate electrode 20b and the same electrical signal is applied to the first sub-electrode 51 and the second sub-electrode 52, the semiconductor device 104 may operate as one transistor.

In some example embodiments, electrical signals are independently applied to the first gate electrode 20a and the second gate electrode 20b and electrical signals are independently applied to the first sub-electrode 51 and the second sub-electrode 52, and the semiconductor device 1 may operate as two transistors. For example, the oxide semiconductor layer 10, the first gate electrode 20a, the first gate insulating layer 30a, the first electrode 40, the first sub-electrode 51, the first metal nitride layer 60a, the first metal oxide layer 70a, the first sub-metal nitride layer 61, and the first sub-metal oxide layer 71 operate as one transistor, and the oxide semiconductor layer 10, the second gate electrode 20b, the second gate insulating layer 30b, the first electrode 40, the second sub-electrode 52, the first metal nitride layer 60a, the first metal oxide layer 70a, the second sub-metal nitride layer 62, and the second sub-metal oxide layer 72 may operate as another transistor.

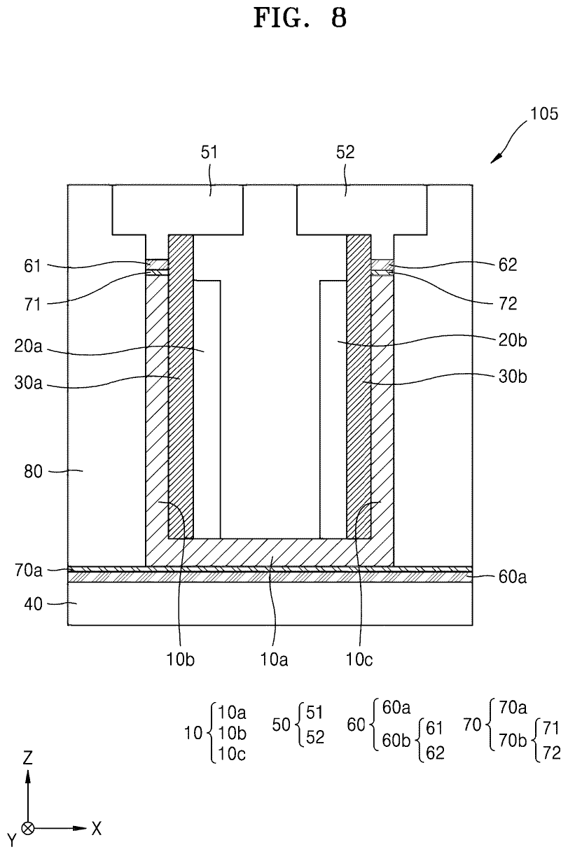

FIG. 8 is a diagram showing a semiconductor device 105 according to another example embodiment. In FIG. 8, components indicated by the same reference numerals as those of FIG. 7 have substantially the same structures and operating effects, and detailed descriptions thereof are omitted.

When comparing FIG. 7 with FIG. 8, the width W1 of the first metal oxide layer 70a in the direction (X-axis direction) parallel to the surface of the first electrode 40 may be greater than the width of the oxide semiconductor layer 10. For example, the width of the first metal oxide layer 70a may be equal to the width of the first metal nitride layer 60a. The first metal oxide layer 70a of FIG. 7 is formed on the first metal nitride layer 60a after forming the insulating layer 80, whereas the first metal oxide layer 70a of FIG. 8 may be formed on the first metal nitride layer 60a and then the insulating layer 80 may be formed on the first metal oxide layer 70a.

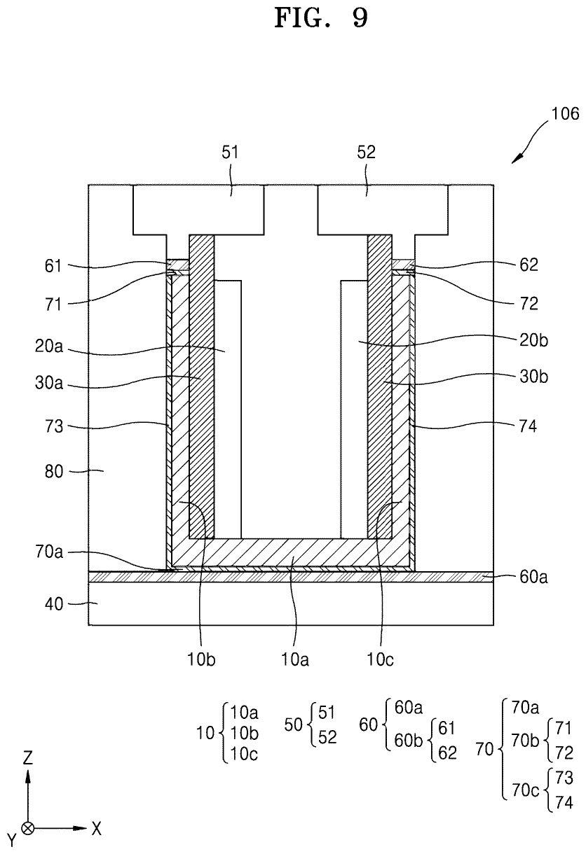

FIG. 9 is a diagram showing a semiconductor device 106 according to another example embodiment. In FIG. 9, components indicated by the same reference numerals as those of FIG. 7 have substantially the same structures and operating effects, and detailed descriptions thereof are omitted.

When comparing FIG. 7 with FIG. 9, the semiconductor device 106 of FIG. 9 may further include a third metal oxide layer 70c surrounding the side surface of the oxide semiconductor layer 10. The third metal oxide layer 70c may not overlap the oxide semiconductor layer 10 in the direction perpendicular to the surface of the first electrode 40. For example, the third metal oxide layer 70c may surround the outer surface of the oxide semiconductor layer 10. One end of the third metal oxide layer 70c is in contact with the first metal oxide layer 70a, and the other end of the third metal oxide layer 70c may be in contact with the second metal oxide layer 70b. In addition, the inner surface of the third metal oxide layer 70c may be in contact with the oxide semiconductor layer 10. The third metal oxide layer 70c may include a third sub-metal oxide layer 73 disposed on the outer surface of the first vertical extension portion 10b of the oxide semiconductor layer 10, and a fourth sub-metal oxide layer 74 disposed on the outer surface of the second vertical extension portion 10c of the oxide semiconductor layer 10.

Although not shown in the drawing, the metal nitride layer may further include an additional metal nitride layer surrounding the outer surface of the third metal oxide layer 70c.

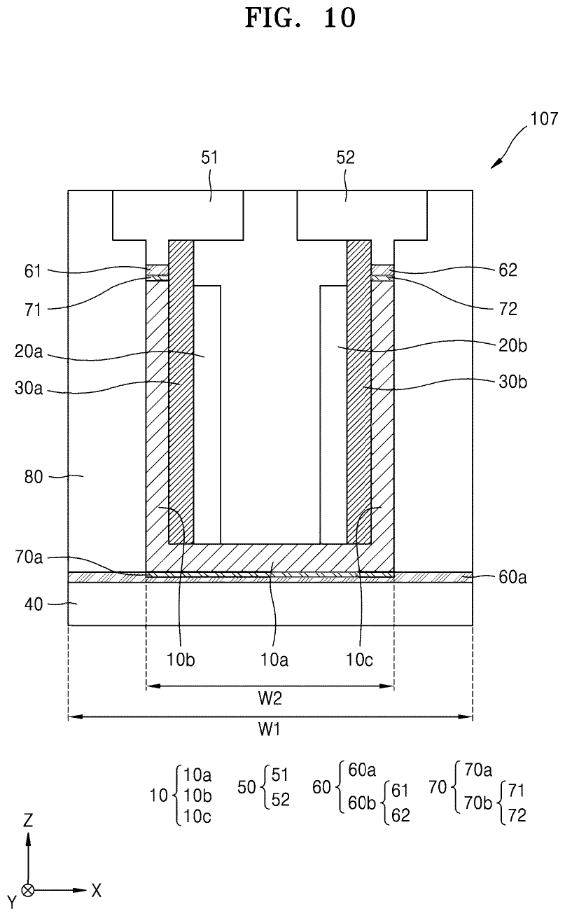

FIG. 10 is a diagram showing a semiconductor device 107 according to another example embodiment. In FIG. 10, components indicated by the same reference numerals as those of FIG. 7 have substantially the same structures and operating effects, and detailed descriptions thereof are omitted.

Comparing FIG. 7 with FIG. 10, in the semiconductor device 107 of FIG. 10, a width of the first metal oxide layer 70a in the direction parallel to the surface of the first electrode 40 may be less than the width W1 of the first metal nitride layer 60a. For example, the width of the first metal oxide layer 70a may be equal to the width W2 of the oxide semiconductor layer 10. The surface of the first metal nitride layer 60a may be stepped due to the first metal oxide layer 70a. For example, a partial region of the first metal nitride layer 60a may be doped and oxidated by the first metal in the oxide semiconductor layer 10, and then, may become the first metal oxide layer 70a.

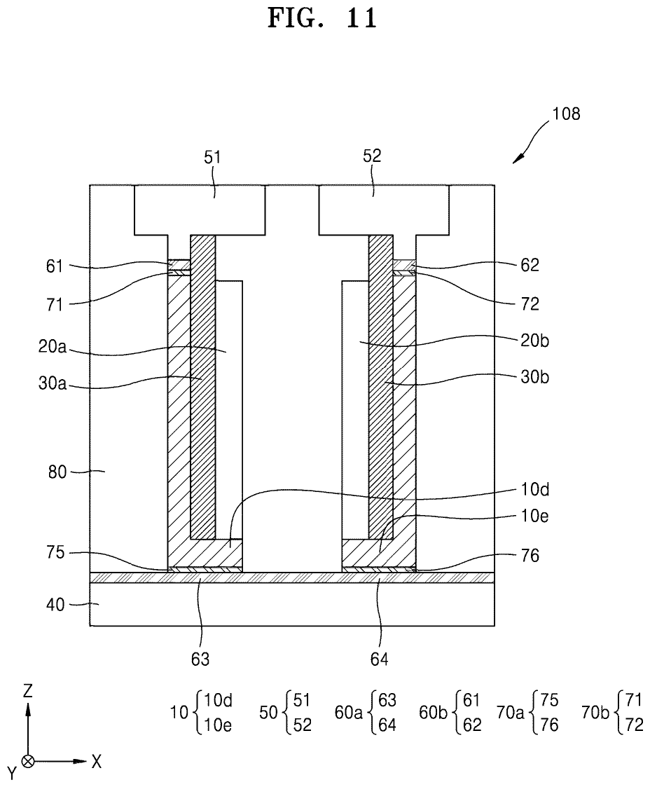

FIG. 11 is a diagram of a semiconductor device 108 according to another example embodiment. In FIG. 11, components indicated by the same reference numerals as those of FIG. 7 have substantially the same structures and operating effects, and detailed descriptions thereof are omitted.

When comparing FIG. 1 with FIG. 11, a shape of the oxide semiconductor layer 10 included in the semiconductor device 108 of FIG. 11 may be different from that of the oxide semiconductor layer 10 included in the semiconductor device 104 of FIG. 7. The semiconductor device 108 may include a first oxide semiconductor layer 10d and a second oxide semiconductor layer 10e. The first oxide semiconductor layer 10d has an L-shaped cross-section, and the second oxide semiconductor layer 10e may have a cross-sectional shape that is symmetrical to the first oxide semiconductor layer 10d with respect to the Z-axis. The first oxide semiconductor layer 10d and the second oxide semiconductor layer 10e are separated from each other.

The first oxide semiconductor layer 10d and the second oxide semiconductor layer 10e may be each located so that a longer side thereof may be arranged in a direction (Z-axis direction) perpendicular to the surface of the first electrode 40.

The first metal nitride layer 60a may include a third sub-metal nitride layer 63 disposed between the first oxide semiconductor layer 10d and the first electrode 40, and a fourth sub-metal nitride layer 64 disposed between the second oxide semiconductor layer 10e and the second electrode 50. The third sub-metal nitride layer 63 and the fourth sub-metal nitride layer 64 may be spatially spaced apart from each other or may be connected integrally to each other.

The first metal oxide layer 70a may include a fifth sub-metal oxide layer 75 disposed between the third sub-metal nitride layer 63 and the first oxide semiconductor layer 10d, and a sixth sub-metal oxide layer 76 disposed between the fourth sub-metal nitride layer 64 and the second oxide semiconductor layer 10e. The fifth sub-metal oxide layer 75 and the sixth sub-metal oxide layer 76 are spatially spaced apart from each other, or may be connected integrally to each other. Although not shown in the drawing, the metal oxide layer may further include a third nitride layer surrounding the outer surface of each of the first oxide semiconductor layer 10d and the second oxide semiconductor layer 10e.

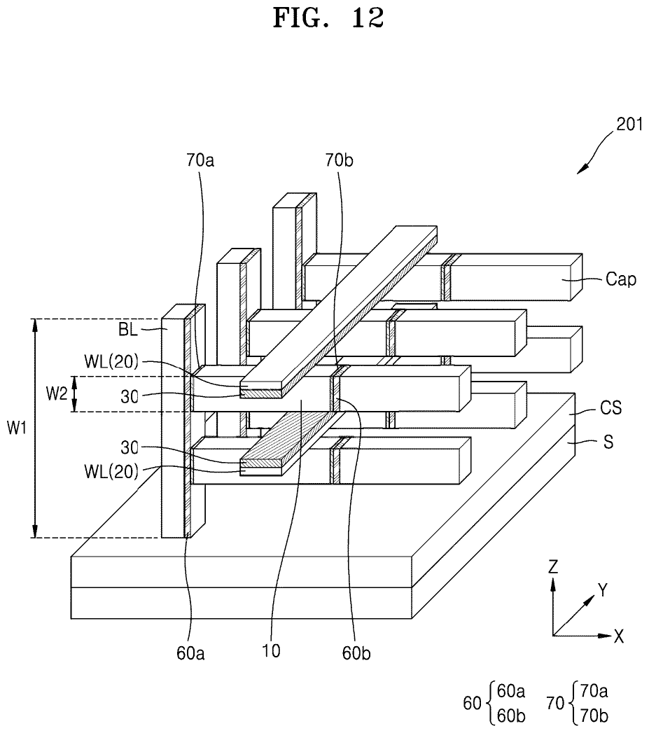

FIG. 12 is a perspective view showing an example of a schematic structure of a vertical stack memory device 201 according to an example embodiment. Referring to FIG. 12, the vertical stack memory device 201 may include a plurality of bit lines BL extending in the first direction (that is, Z-axis direction), a plurality of oxide semiconductor layers 10 connected to the plurality of bit lines BL, respectively, and extending in a second direction (that is, X-axis direction) intersecting with the first direction, a plurality of capacitors Cap electrically connected to the plurality of oxide semiconductor layers 10, respectively, and a plurality of word lines WL extending to cross the plurality of oxide semiconductor layers 10 in a third direction (that is, Y-axis direction) that perpendicularly crosses the first and second directions. FIG. 12 shows that each of the plurality of word lines WL crosses over a corresponding oxide semiconductor layer 10 from among the plurality of oxide semiconductor layer 10, but example embodiments are not limited thereto, and the word line WL may cross under the oxide semiconductor layer 10.

Also, the vertical stack memory device 201 may further include a growth substrate S and a drive circuit substrate CS disposed on the growth substrate S. The drive circuit substrate CS may include circuits connected to external circuits for performing input/output operations of receiving data from the outside or outputting data to the outside, and operations of recording data on the capacitor Cap or receiving data recorded on the capacitor Cap.

The plurality of bit lines BL may be provided on the drive circuit substrate CS to be perpendicular to the upper surface of the drive circuit substrate CS. FIG. 12 shows only three bit lines BL that are arranged in a row with an interval therebetween in the third direction for the convenience of description, but more bit lines BL may be actually arranged two-dimensionally. For example, the plurality of bit lines BL extending in the vertical direction, that is, the first direction, may be two-dimensionally arranged on the drive circuit substrate CS with certain intervals in the second and third directions. The plurality of bit lines BL may be parallel to each other.

The plurality of oxide semiconductor layers 10 connected to one corresponding bit line BL from among the plurality of bit lines BL may be arranged with certain intervals therebetween in the first direction. FIG. 12 only shows two oxide semiconductor layers 10 with respect to one bit line BL, but more than two oxide semiconductor layers 10 may be arranged with certain intervals therebetween in the first direction. Also, the plurality of oxide semiconductor layers 10 may be arranged parallel to each other with certain intervals therebetween in the third direction in the same layer. The plurality of oxide semiconductor layers 10 arranged in the same layer may be connected to corresponding bit lines BL that are different from each other, from among the plurality of bit lines BL, respectively. The plurality of oxide semiconductor layers 10 may be two-dimensionally arranged with certain intervals therebetween in the second and third directions, like the plurality of bit lines BL. Each of the plurality of oxide semiconductor layers 10 may extend in the second direction. A first end portion in each of the plurality of oxide semiconductor layers 10 may electrically connected to one corresponding bit line from among the plurality of bit lines BL. A second end portion in each of the plurality of oxide semiconductor layers 10, which is opposite to the first end portion in the second direction, may be electrically connected to the capacitor Cap.

The first metal nitride layer 60a may be disposed between the oxide semiconductor layer 10 and the bit line BL, and the first metal oxide layer 70a may be disposed between the oxide semiconductor layer 10 and the first metal nitride layer 60a. Also, the second metal nitride layer 60b may be disposed between the oxide semiconductor layer 10 and the capacitor, and the second metal oxide layer 70b may be disposed between the oxide semiconductor layer 10 and the second metal nitride layer 60b. In the drawing, the metal nitride layer 60 and the metal oxide layer 70 are arranged at both ends of the oxide semiconductor layer 10, but example embodiments are not limited thereto. The metal nitride layer 60 and the metal oxide layer 70 may be arranged at only one end of the oxide semiconductor layer 10.

In FIG. 12, a width of the first metal oxide layer 70a is equal to the width W2 of the oxide semiconductor layer 10, but example embodiments are not limited thereto. In some example embodiments, a width of the first metal oxide layer 70a may be greater than the width W2 of the oxide semiconductor layer 10. In some example embodiments, the width of the first metal oxide layer 70a may be equal to the width W1 of the first metal nitride layer 60a. In some example embodiments, the first metal nitride layer 60a may be stepped due to the first metal oxide layer 70a. In some example embodiments, the memory device 201 may further include a third metal oxide layer (not shown) surrounding the outer surface of the oxide semiconductor layer 10, and one end of the third metal oxide layer may come into contact with the first metal oxide layer 70a and the other end of the third metal oxide layer may come into contact with the second metal oxide layer 70b.

In FIG. 12, the capacitor Cap is represented as one block for the convenience of description, but the capacitor Cap may actually include the first electrode, the second electrode, and a dielectric layer disposed between the first electrode and the second electrode. The first electrode of the capacitor Cap may be electrically connected to the second end portion of the corresponding oxide semiconductor layer 10, from among the plurality of oxide semiconductor layers 10. Therefore, one oxide semiconductor layer 10 and one capacitor Cap may be connected to each other in a one-to-one correspondence. Although not shown in the drawing, the second electrode of the capacitor Cap may be connected to a ground line of the vertical stack memory device 201.

The word line WL may extend in the third direction so as to cross over the plurality of corresponding oxide semiconductor layers 10. Also, the plurality of word lines WL may be arranged with certain intervals therebetween in the first direction. FIG. 12 only shows one word line WL arranged in one layer for convenience of description, but a plurality of word lines WL may be arranged parallel to each other with certain intervals in the second direction on one layer.

The gate insulating layer 30 is disposed between the oxide semiconductor layer 10 and the word line WL. Although not shown in FIG. 12, the vertical stack memory device 201 may further include an insulator material filled in spaced between the plurality of bit lines BL, between the plurality of oxide semiconductor layers 10, and between the plurality of word lines WL.

One oxide semiconductor layer 10 may form one oxide semiconductor transistor along with one word line WL and bit line BL corresponding thereto, and the first electrode of the capacitor. The first electrode 40 of the oxide semiconductor transistor may be a component of the bit line BL, the gate electrode 20 may be a component of the word line WL, and the second electrode 50 may be the first electrode of the capacitor Cap. However, example embodiments are not limited thereto. The first electrode 40, the gate electrode 20, and the second electrode 50 may be provided as separate layers, and may be electrically connected to the bit line BL, the word line WL, and the first electrode of the capacitor Cap.

Because the word line WL may function as the gate electrode 20 of the oxide semiconductor transistor, when a gate signal of a threshold voltage or greater is applied to the word line WL, the current may flow along the oxide semiconductor layer 10. Then, the bit line BL and the capacitor Cap corresponding to each other are electrically connected to each other, and thus, data may be recorded on the capacitor Cap or data recorded on the capacitor Cap may be read.

Therefore, one oxide semiconductor layer 10 and one capacitor Cap corresponding to the oxide semiconductor layer may form one memory cell. The vertical stack memory device 201 according to the example embodiment may include a plurality of memory cells arranged two-dimensionally on one layer. Also, the vertical stack memory device 201 may have a plurality of layers that are stacked, each layer including the plurality of memory cells that are two-dimensionally arranged. Therefore, an integration degree of the memory cells increases, and recording capacity of the vertical stack memory device 201 may be improved.

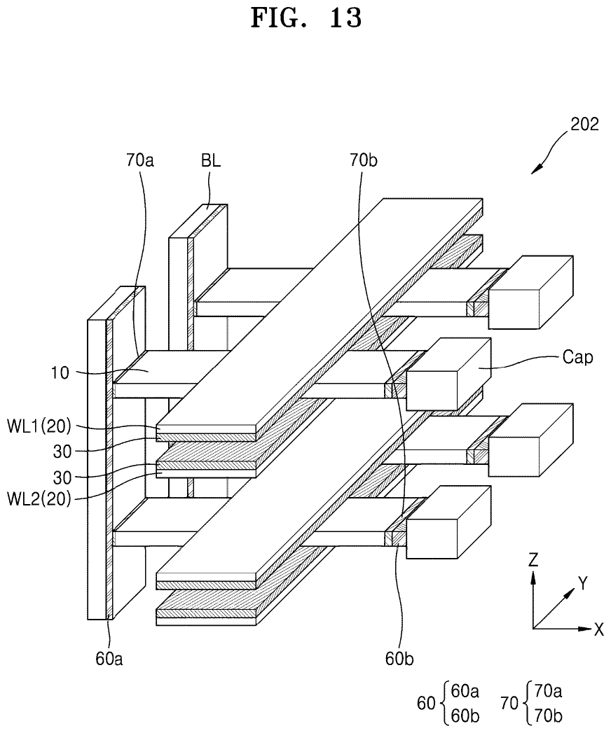

FIG. 13 is a perspective view showing an example of a schematic structure of a vertical stack memory device 202 according to another example embodiment. Referring to FIGS. 12 and 13, the vertical stack memory device 202 of FIG. 13 may have a dual-gate structure. For example, the vertical stack memory device 202 may include a first word line WL1 extending in the third direction so as to cross over the plurality of oxide semiconductor layers 10 arranged in the same layer, and a second word line WL2 extending in the third direction so as to cross under the plurality of oxide semiconductor layers 10 arranged in the same layer. The first word line WL1 and the second word line WL2 may be arranged parallel to each other so as to face each other while being spaced apart from each other in the first direction with the corresponding oxide semiconductor layer 10 interposed therebetween. In other words, each of the plurality of word lines WL shown in FIG. 13 includes the first word line WL1 and the second word line WL2 that are arranged parallel to each other so as to face each other while being spaced apart from each other in the first direction with the corresponding oxide semiconductor layer 10, from among the plurality of oxide semiconductor layers 10, interposed therebetween.

One oxide semiconductor layer 10 may form one oxide semiconductor transistor along with the first word line WL1 and the second word line WL2 corresponding thereto. Operations of one oxide semiconductor transistor may be controlled by the first word line WL1 disposed above the oxide semiconductor layer 10 and the second word line WL2 disposed under the oxide semiconductor layer 10. Therefore, the driving reliability of the oxide semiconductor transistor may be improved. The other components in the vertical stack memory device 202 shown in FIG. 13 may be the same as or substantially similar to the structures of the vertical stack memory device 201 shown in FIG. 12, and thus, detailed descriptions thereof are omitted.

In FIGS. 12 and 13, the bit lines BL are arranged perpendicularly to the upper surface of the drive circuit substrate CS, and the word lines WL are arranged parallel to the upper surface of the drive circuit substrate CS. However, example embodiments are not limited thereto. The bit lines BL may be arranged parallel to the upper surface of the drive circuit substrate CS, and the word lines WL may be arranged perpendicularly to the upper surface of the drive circuit substrate CS. That is, the oxide semiconductor layer 10 and the capacitor Cap may be sequentially arranged from the drive circuit substrate CS.

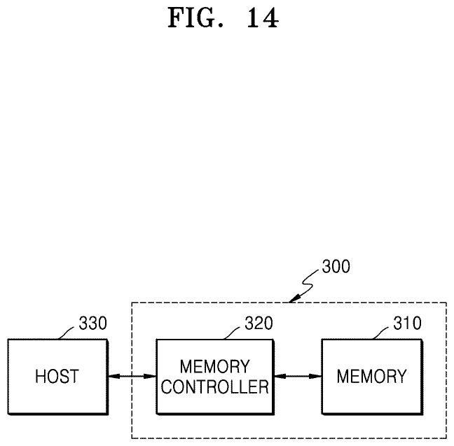

FIG. 14 is a block diagram of an electronic system 300 according to an example embodiment.

The electronic system 300 includes a memory 310 and a memory controller 320. The memory controller 320 may control the memory 310 in response to a request from a host 330, for reading and/or writing data from/into the memory 310. At least one of the memory 310 or the memory controller 320 may include the semiconductor device 1 according to the above-described example embodiment.

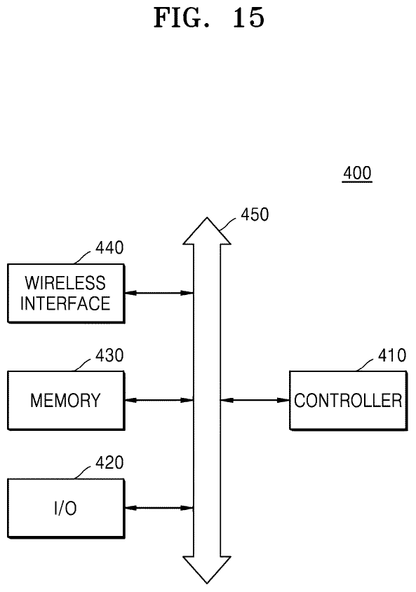

FIG. 15 is a block diagram of an electronic system 400 according to an example embodiment.

The electronic system 400 may configure a wireless communication device or a device capable of transmitting and/or receiving information under wireless environment. The electronic system 400 includes a controller 410, an input/output device (I/O) 420, a memory 430, and a wireless interface 440, which are connected to one another via a bus 450.

The controller 410 may include a microprocessor, a digital signal processor, or at least one of similar processing devices. The I/O 420 may include at least one of a keypad, a keyboard, and a display. The memory 430 may be used to store commands executed by the controller 410. For example, the memory 430 may be used to store user data. The electronic system 400 may use the wireless interface 440 for transmitting/receiving data via a wireless communication network. The wireless interface 440 may include an antenna and/or a wireless transceiver. The electronic system 400 may include the semiconductor device according to the one or more example embodiments described above.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While semiconductor devices and electronic apparatuses including the semiconductor devices have been particularly shown and described with reference to some example embodiments thereof, it will be understood by those of ordinary skill in the art that various changes in form and details may be made therein without departing from the spirit and scope as defined by the following claims. In the specification, many details are described in detail, but they are not provided to limit the scope of the disclosure, and should be interpreted as illustrating the example embodiment. Thus, the scope of the disclosure should be determined by the technical idea set forth in the claims, not by the embodiments.

Semiconductor devices according to some example embodiments may reduce or prevent a material in an oxide semiconductor layer from diffusing to a metal layer, because a metal nitride layer is disposed between the oxide semiconductor layer and the metal layer.

Semiconductor device according to some example embodiments may improve degradation in the contact resistance because a low-resistive oxide layer including metal of a metal nitride layer is disposed between a metal nitride layer and an oxide semiconductor layer.

Semiconductor device according to some example embodiments may maintain the thermal stability at a relatively high temperature.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
an oxide semiconductor layer including a first metal;
a first electrode and a second electrode spaced apart from each other on the oxide semiconductor layer;
a metal nitride layer between at least one of the first electrode and the second electrode and the oxide semiconductor layer, the metal nitride layer including a second metal that is different from the first metal;
a metal oxide layer between the metal nitride layer and the oxide semiconductor layer, the metal oxide layer including the first metal and the second metal;
a gate electrode spaced apart from the oxide semiconductor layer; and
a gate insulating layer between the oxide semiconductor layer and the gate electrode,
wherein a content of the first metal in the metal oxide layer is less than a content of the first metal in the oxide semiconductor layer.

2. The semiconductor device of claim 1, wherein
the content of the first metal in the metal oxide layer is less than a content of the second metal in the metal oxide layer.

3. The semiconductor device of claim 1, wherein
the content of the first metal in the metal oxide layer is less than or equal to 10 at %.

4. The semiconductor device of claim 1, wherein
the metal nitride layer has 0 at % of oxygen.

5. The semiconductor device of claim 1, wherein
the metal oxide layer further includes nitrogen.

6. The semiconductor device of claim 1, wherein
a content of nitrogen decreases from the metal nitride layer toward the oxide semiconductor layer.

7. The semiconductor device of claim 1, wherein
at least one of the metal nitride layer or the metal oxide layer further includes silicon (Si).

8. The semiconductor device of claim 1, wherein
the second metal is different from a third metal included in an electrode in contact with the metal nitride layer from among the first electrode and the second electrode.

9. The semiconductor device of claim 1, wherein
the first metal includes at least one of indium (In), gallium (Ga), tin (Sn), cadmium (Cd), aluminum (Al), germanium (Ge), or hafnium (Hf).

10. The semiconductor device of claim 1, wherein
the second metal includes at least one of Ga, tungsten (W), zinc (Zn), vanadium (V), titanium (Ti), molybdenum (Mo), niobium (Nb), or tantalum (Ta).

11. The semiconductor device of claim 1, wherein
the metal nitride layer includes TiN, and
the metal oxide layer includes InTiO, and a content of indium in the metal oxide layer is 10 at % or less.

12. The semiconductor device of claim 1, wherein
a thickness of the metal oxide layer is less than a thickness of the metal nitride layer.

13. The semiconductor device of claim 1, wherein
a thickness of the metal oxide layer is half a thickness of the metal nitride layer or less.

14. The semiconductor device of claim 1, wherein
a contact resistance between the oxide semiconductor layer and one electrode in contact with the metal nitride layer from among the first electrode and the second electrode is 3E−2 Ω·cm² or less.

15. The semiconductor device of claim 1, wherein
the first electrode, the metal nitride layer, the metal oxide layer, the oxide semiconductor layer, and the second electrode are sequentially arranged in a direction perpendicular to a surface of the first electrode.

16. The semiconductor device of claim 15, wherein
a width of the metal oxide layer is equal to a width of the metal nitride layer.

17. The semiconductor device of claim 15, wherein
the oxide semiconductor layer includes
a first region extending in a direction parallel to the surface of the first electrode, and
a second region extending from the first electrode to the second electrode, in a direction perpendicular to the surface of the first electrode.

18. The semiconductor device of claim 17, wherein
the metal oxide layer includes
a third region between the metal nitride layer and the first region of the oxide semiconductor layer, and
a fourth region surrounding an outer surface of the second region.

19. The semiconductor device of claim 1, wherein
the metal nitride layer includes
a first metal nitride layer between the first electrode and the oxide semiconductor layer, and
a second metal nitride layer between the second electrode and the oxide semiconductor layer, and
the metal oxide layer includes
a first metal oxide layer between the first metal nitride layer and the oxide semiconductor layer, and
a second metal oxide layer between the second metal nitride layer and the oxide semiconductor layer.

20. The semiconductor device of claim 1, further comprising:
a capacitor electrically connected to the oxide semiconductor layer,
wherein the first electrode is a component of a bit line and a gate electrode is a component of a word line.
